(19) United States
(12) Patent Application Publication
(10) Pub. No.: US 2026/0255902 A1
(43) Pub. Date: Aug. 27, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: TZU JUNG TIEN, HSINCHU COUNTY (TW); JEN-YUAN CHANG, HSINCHU CITY (TW)

(21) Appl. No.: 19/062,074

(22) Filed: Feb. 25, 2025

(51) Int. Cl. H01L 21/78; H01L 21/268; H01L 21/304; H10D 62/10

(52) U.S. Cl. CPC H10P 54/00; H10D 62/117; H10P 34/42; H10P 52/00

(57) ABSTRACT

A semiconductor structure includes a substrate and a plurality of structure units. The plurality of structure units are bonded onto the substrate. Each of the plurality of structure units includes a bottom structure and a top structure. The bottom structure of the structure unit is bonded onto the substrate and has a width gradually increased from a top to a bottom. The top structure of the structure unit is formed on the bottom structure.

### BACKGROUND

Semiconductor structures are used in a variety of electronic applications, such as personal computers, cell phones, digital cameras, and other electronic devices. Semiconductor devices are typically manufactured by sequentially depositing various insulating or dielectric layers, conductive layers, and semiconductive material layers over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, for example in multichip modules or in other types of packages.

The semiconductor industry is continually improving the integration density of various electronic components (e.g. transistors, diodes, resistors, capacitors, etc.) by continually reducing the minimum feature size, allowing more components to be integrated into a given area. These smaller electronic components require smaller and more advanced packaging systems than past packages in some applications.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A, 1B, 2A and 2B illustrate cross-sectional views of a structure unit of a semiconductor structure in accordance with various embodiments of the present disclosure.

FIG. 3A illustrates an enlarged cross-sectional view of a portion A shown in FIG. 2A, in accordance with some embodiments of the present disclosure.

FIG. 3B illustrates an enlarged cross-sectional view of a portion A shown in FIG. 2A, in accordance with some another embodiments of the present disclosure.

FIGS. 4A, 4B and 4C illustrate cross-sectional side views of three-dimensionally (3D) stacking dies of a semiconductor structure in accordance with various embodiments of the present disclosure.

FIG. 5A illustrates a cross-sectional side view of a package die of a semiconductor structure in accordance with some embodiments of the present disclosure.

FIG. 5B illustrates a cross-sectional side view of a package die including the 3D stacking dies shown in FIG. 4A of a semiconductor structure in accordance with some embodiments of the present disclosure.

FIG. 6 is a flowchart of a method for forming the semiconductor device in accordance with some embodiments.

FIGS. 7A to 7I illustrate various perspective views of forming the semiconductor device in accordance with some embodiments as described in FIG. 6.

FIG. 8 illustrates an enlarged cross-sectional view of a portion B shown in FIG. 7F, in accordance with some embodiments of the present disclosure.

FIGS. 9A to 9J illustrate various perspective views of forming the semiconductor device in accordance with some embodiments as described in FIG. 9G.

FIG. 10 illustrates an enlarged cross-sectional view of a portion C shown in FIG. 9J, in accordance with some embodiments of the present disclosure.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

In three-dimensional integrated circuit (3DIC) formation process, device dies may be bonded to a wafer. Typically, after the bonding of the dies onto the wafer, a molding compound is applied to encapsulate the device dies and the wafer. Solder bumps are formed on the wafer to electrically couple to the devices in the wafer. The electrical connection to the devices in the device dies and the devices in the wafer includes through-silicon vias (TSVs).

To separate a wafer or device dies into individual dies, a sawing process may be performed on a device layer while a laser grooving process can performed on a wafer. A shallow groove formed in the device layer by the sawing process would be wider than a deeper groove formed in the wafer. After the sawing process, the dies can be flipped and bonded onto a substrate. Each of the die bonding to the substrate would have a bottom portion (i.e., the device layer) with a narrower width due to the wider shallow groove and a top portion (i.e., the wafer) with a wider width due to the narrower deeper groove. Since the bottom portion is narrower than the top portion, gap filling material cannot deposited beside the bottom portion and thus voids would be formed beside the bottom portion, which would deteriorate the performance of the semiconductor structure.

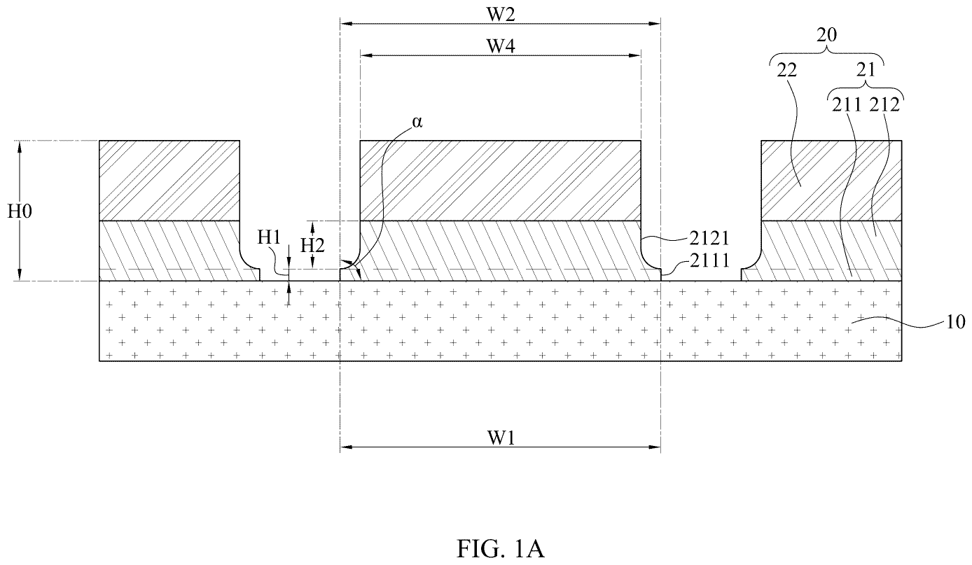

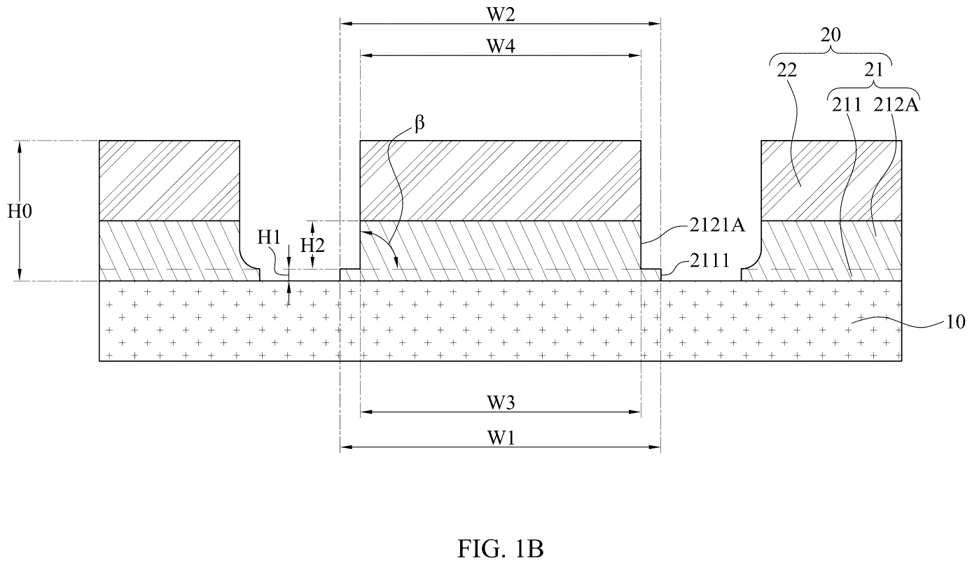

Referring to FIG. 1A, the semiconductor structure comprises a substrate 10 and a plurality of structure units 20 bonded onto the substrate 10. The substrate 10 may be a wafer with a plurality of integrated circuit dies formed thereon. In some alternative embodiments, the substrate 10 may be a carrier wafer. The carrier wafer may be a glass carrier substrate, a ceramic carrier substrate, or the like.

Each of the plurality of structure units 20 comprises a bottom structure 21 and a top structure 22. Each of the plurality of structure units 20 has a total height H0. The bottom structure 21 is bonded onto the substrate 10. The bottom structure 21 comprises a lower portion 211 and an upper portion 212. The bottom structure 21 may include, but not limited to, at least a portion of a front-end structure, at least a portion of a middle-end structure, at least a portion of a back-end structure, both of the front-end structure and the middle-end structure, both of the back-end structure and the middle-end structure, three-dimensionally (3D) stacking dies and so on. In some embodiments, the bottom structure 21 may be a device layer. A device layer may include a group III-V compound, such as aluminum gallium nitride (AlGaN), and an III-N (tri nitride) compound, such as gallium nitride (GaN). A wide bandgap of the III-V compound forms a heterojunction with a narrow bandgap of the III-N compound. Lattice constants of these two materials are typically slightly different, which produces a strain that can result in pizeoelectrically-induced polarization band bending at the heterojunction interface.

The lower portion 211 has a bottom, a top and a lower sidewall 2111 coupling to the bottom and top of the lower portion 211. The lower portion 211 may have a first height H1 measured in a direction from the bottom to the top. The bottom is bonded onto the substrate 10 and has a first width W1. The top has a second width W2, which can be equal to or less than the first width W1. In some embodiments as shown in FIG. 1A, the second width W2 can be equal to the first width W1, so that the lower portion 211 may have a rectangular cross section. The lower sidewall 2111 can be formed after being treated with a first sawing process, including a blade sawing, a laser grooving, a plasma dicing, a solid-impact surface treatment (such as sandblasting), a non-solid-impact surface treatment (such as water gun) or the like, or a combination thereof. In some embodiments, the first sawing process may be a blade sawing. The lower sidewall 2111 may be substantially linear, which may extend from the substrate 10 toward the upper portion 212. In some embodiments, an angle α between the bottom of the lower portion 211 and the lower sidewall 2111 may be equal to or less than 90 degrees. Therefore, the lower sidewall 2111 may be substantially perpendicular to a horizontal line that is parallel to a bottom of the lower portion 211, or in some embodiments, the lower sidewall 2111 may be in a slope form. These are, of course, merely examples and are not intended to be limiting.

In some embodiments, a ratio of the first height H1 to the total height H0 may be less than about 50%. In some embodiments, a ratio of the first height H1 to the total height H0 may range from about 1:2 to about 1:100. In some embodiments, a ratio of the first height H1 to the total height H0 may range from about 1:5 to about 1:80. In some embodiments, a ratio of the first height H1 to the total height H0 may range from about 1:10 to about 1:50.

The upper portion 212 has an upper sidewall 2121, which is formed after being treated with a second sawing process, which can be different from the first sawing process to form the lower sidewall 2111 of the lower portion 211. The second sawing process may include a blade sawing, a laser grooving, a plasma dicing, a solid-impact surface treatment (such as sandblasting), a non-solid-impact surface treatment (such as water gun) or the like, or a combination thereof. In some embodiments, the second sawing process may be a laser grooving. As shown in FIG. 1A, the upper portion 212 may be in a tapered form with a wider bottom and a narrower top. In some embodiments, the upper sidewall 2121 has at least one curved segment and at least one linear segment. The at least one curved segment may extend from the lower sidewall 2111 and the at least one linear segment may extend from the at least one curved segment toward the upper portion 212.

The upper portion 212 may have a rectangular cross-section and the upper sidewall 2121A of the upper portion 212 may be linear as shown in FIG. 1B. An angle β between the upper sidewall 2121A and a horizontal line may be 90 degrees or less than 90 degrees. In some embodiments, the upper sidewall 2121A may be substantially perpendicular to a horizontal line and thus the angle β between the upper sidewall 2121A and a horizontal line can be 90 degrees. The upper portion 212 has a third width W3, which may be less than the first width W1 and may be equal to or less than the second width W2. In some embodiments, the third width W3 may be less than the second width W2. In some embodiments, a ratio of the first width W1 to the third width W3 may range from about 1:1 to about 15:1. In some embodiments, the ratio of the first width W1 to the third width W3 may range from about 5:4 to about 10:1. In some embodiments, the ratio of the first width W1 to the third width W3 may range from about 3:2 to about 5:1. In some embodiments, a ratio of the third width W3 to the second width W2 may range from about 100:99 to about 2:1. In some embodiments, a ratio of the third width W3 to the second width W2 may range from about 10:9 to about 5:3. In some embodiments, a ratio of the third width W3 to the second width W2 may range from about 5:4 to about 10:7.

In some embodiments, the upper portion 212 has a second height H2, which may be less than, equal to or greater than the first height H1. In some embodiments, a ratio of the first height H1 to the second height H2 may range from about 20:1 to about 1:50. In some embodiments, a ratio of the first height H1 to the second height H2 may range from about 1:1 to about 1:35. In some embodiments, a ratio of the first height H1 to the second height H2 may range from about 1:10 to about 1:20. In some embodiments, the second height H2 may be greater than the first height H1 and the difference the second height H2 and the first height H1 may range from about 0.5 μm to about 10 μm. In some embodiments, the difference the second height H2 and the first height H1 may range from about 1 μm to about 5 μm.

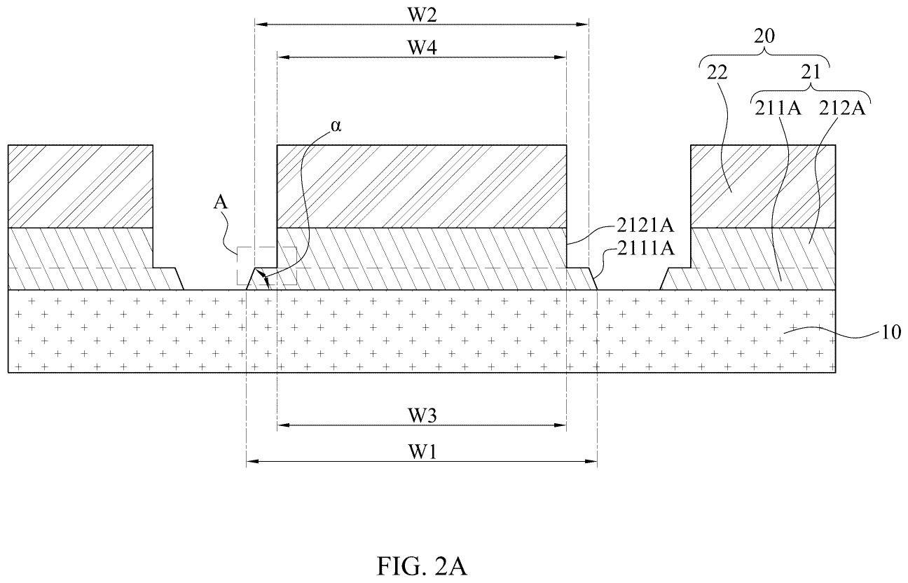

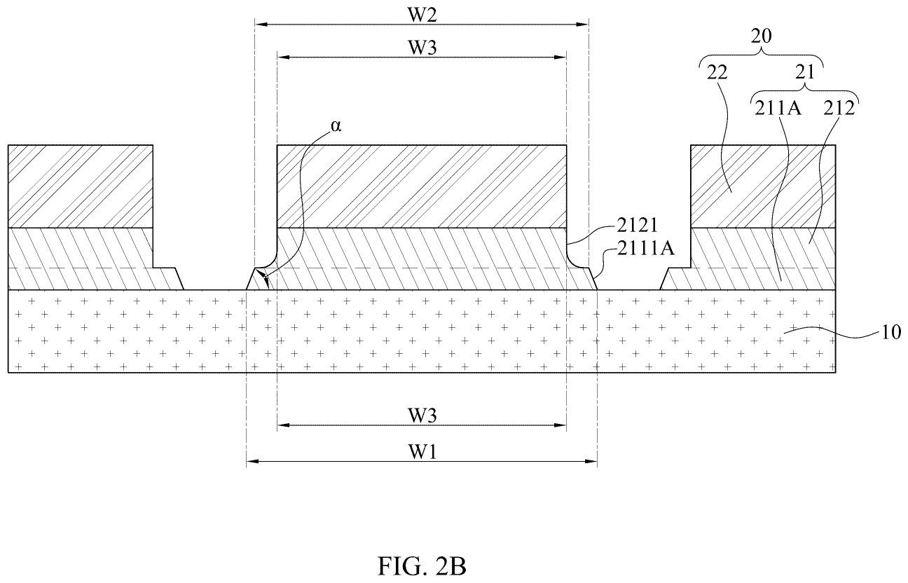

In some alternative embodiments as shown in FIG. 2A, the lower portion 211A may have a trapezoid cross section. In some embodiments, the second width W2 is less than the first width W1. In some embodiments, a ratio of the first width W1 to the second width W2 may range from about 1:1 to about 10:1. In some embodiments, the ratio of the first width W1 to the second width W2 may range from about 10:9 to about 5:1. In some embodiments, the ratio of the first width W1 to the second width W2 may range from about 5:4 to about 3:1. Therefore, the lower portion 211 may be in a tapered form. The angle α between the bottom of the lower portion 211A and the lower sidewall 2111A may be less than about 90 degrees and greater than 0 degrees. In some embodiments, the angle α may range from about 15 degrees to about 75 degrees. In some embodiments, the angle α may range from about 30 degrees to about 60 degrees. In some embodiments, the angle α may range from about 40 degrees to about 50 degrees. In some embodiments, the angle α may range from about 25 degrees to about 45 degrees. In some embodiments, the angle α may range from about 35 degrees to about 65 degrees.

The top of the upper portion 212A may be substantially identical in width to the bottom of the upper portion 212A, so that the upper sidewall may be substantially perpendicular to the top of the lower portion 211A. In some embodiments, the top of the upper portion 212A may be substantially identical in width to the bottom of the upper portion 212A so that the upper portion 212A may have a rectangular cross section. The upper sidewall 2121A of the upper portion 212A may be perpendicular to the top of the upper portion 212A. The upper portion 212A has a third width W3, which may be less than the first width W1 and may be equal to or less than the second width W2. In some embodiments, the third width W3 may be less than the second width W2. In some embodiments, a ratio of the first width W1 to the third width W3 may range from about 1:1 to about 15:1. In some embodiments, the ratio of the first width W1 to the third width W3 may range from about 5:4 to about 10:1. In some embodiments, the ratio of the first width W1 to the third width W3 may range from about 3:2 to about 5:1. In some embodiments, a ratio of the third width W3 to the second width W2 may range from about 100:99 to about 2:1. In some embodiments, a ratio of the third width W3 to the second width W2 may range from about 10:9 to about 5:3. In some embodiments, a ratio of the third width W3 to the second width W2 may range from about 5:4 to about 10:7.

As shown in FIG. 2B, the lower portion 211A may have a trapezoid cross section and the upper portion 212 may be in a tapered form with a wider bottom and a narrower top. In some embodiments, the upper sidewall 2121 has at least one curved segment and at least one linear segment. The at least one curved segment may extend from the lower sidewall 2111A and the at least one linear segment may extend from the at least one curved segment toward the upper portion 212.

The top structure 22 is formed over the upper portion 212 of the bottom structure 21 and has a sidewall and a fourth width W4. The top structure 22 may be a wafer. The top structure 22 may include, but not limited to, at least a portion of a front-end structure, at least a portion of a middle-end structure, at least a portion of a back-end structure, both of the front-end structure and the middle-end structure, both of the back-end structure and the middle-end structure, a package carrier and so on. The top structure 22 may have a top, a bottom and a sidewall coupling the top and the bottom. The sidewall of the top structure 22 may be substantially perpendicular to a top surface of the upper portion 212 of the bottom structure 21. The fourth width W4 may be equal to or less than the third width W3 of the upper portion 212. In some embodiments, the fourth width W4 is less than the first width W1 of the lower portion 211 of the bottom structure 21. In some embodiments, a difference between the fourth width W4 and the first width W1 may range from about 1 μm to about 100 μm. In some embodiments, the difference between the fourth width W4 and the first width W1 may range from about 5 μm to about 50 μm. In some embodiments, the difference between the fourth width W4 and the first width W1 may range from about 15 μm to about 30 μm. In some embodiments, the difference between the fourth width W4 and the first width W1 may range from about 20 μm to about 40 μm.

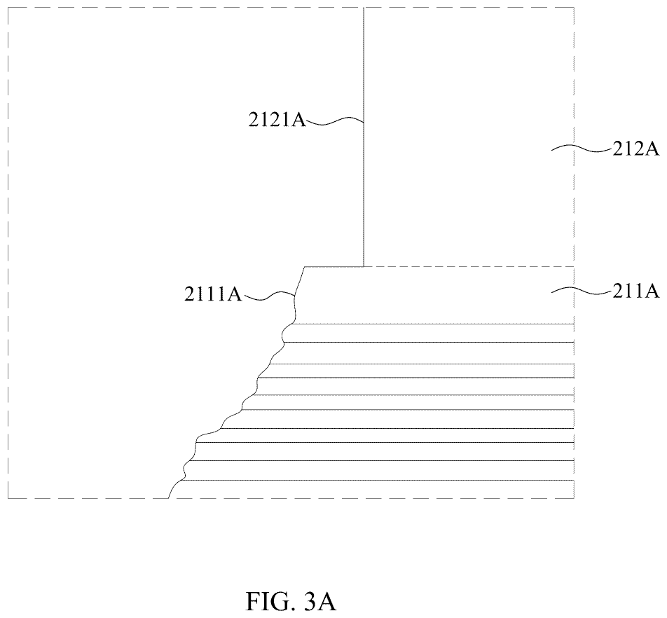

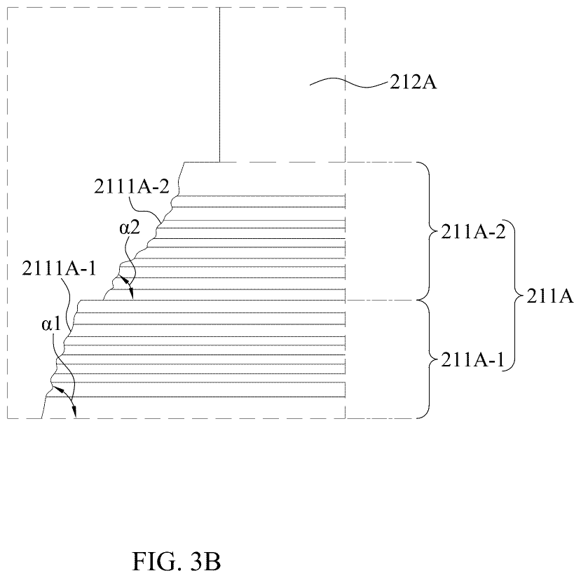

FIG. 3A shows an enlarged cross-sectional view of a portion A circled in FIG. 2A. The angle α between the bottom of the lower portion 211A and the lower sidewall 2111A can be from about 30 degrees to about 60 degrees. The top of the upper portion 212A can be wider than the bottom of the upper portion 212A. The upper sidewall 2121A of the upper portion 212A is perpendicular to the top of the upper portion 212A. In some embodiments, the lower portion 211A may comprise a plurality of layers with identical or different materials. The lower sidewall 2111A may be smooth or rugged. As shown in FIG. 3A, due to different materials used for forming the lower portion 211A, the lower sidewall 2111A is rugged after be treated with a laser grooving procedure or the like.

In some embodiments, the lower portion 211A may comprise a plurality of subportions. As shown in FIG. 3B, the lower portion 211A comprises a first lower subportion 211A-1 and a second lower subportion 211A-2. The first lower subportion 211A-1 is bonded onto the substrate 10 and has a first sidewall 2111A-1 and a first angle α1 between the bottom of the first lower subportion 211A-1 and the first sidewall 2111A-1. In some embodiments, the first angle α1 may range from about 5 degrees to about 90 degrees. In some embodiments, the first angle α1 may range from about 15 degrees to about 75 degrees. In some embodiments, the first angle α1 may range from about 30 degrees to about 60 degrees. The second subportion 211A-2 is overlaid onto the first subportion 211A-1 and has a second sidewall 2111A-2 and a second angle α2 between the bottom of the second lower subportion 211A-2 and the second sidewall 2111A-2. In some embodiments, the second angle α2 may range from about 5 degrees to about 90 degrees. In some embodiments, the second angle α2 may range from about 15 degrees to about 75 degrees. In some embodiments, the second angle α2 may range from about 30 degrees to about 60 degrees. In some embodiments, the second angle α2 may be substantially identical to or different from the first angle α1. In some embodiments, a ratio of the first angle α1 to the second angle α2 may range from about 1:9 to about 9:1. In some embodiments, a ratio of the first angle α1 to the second angle α2 may range from about 1:5 to about 5:1. In some embodiments, a ratio of the first angle α1 to the second angle α2 may range from about 1:3 to about 3:1. As shown in FIG. 3B, the first angle α1 is greater than the second angle α2. In some embodiments, a difference between the first angle α1 and the second angle α2 may be from about 5 degrees to about 85 degrees. In some embodiments, the difference between the first angle α1 and the second angle α2 may be from about 20 degrees to about 75 degrees. In some embodiments, the difference between the first angle α1 and the second angle α2 may be from about 30 degrees to about 60 degrees.

In some embodiments, the first sidewall 2111A-1 may connect continuously or discontinuously to the second sidewall 2111A-2. As shown in FIG. 3B, a bottom of the second subportion 211A-2 is narrower in width than a top of the first subportion 211A-1; therefore, the lower sidewall 2111A may include the first sidewall 2111A-1, the second sidewall 2111A-2 and a portion of the top of the first subportion 211A-1. In some embodiments, the first sidewall 2111A-1 may be smooth or rugged and the second sidewall 2111A-2 may be smooth or rugged. As shown in FIG. 3B, the first lower portion 211A-1 may comprise a plurality of layers with identical or different materials and the second lower portion 211A-2 may comprise a plurality of layers with identical or different materials. The first sidewall 2111A-1 is rugged and the second sidewall 2111A-2 is also rugged.

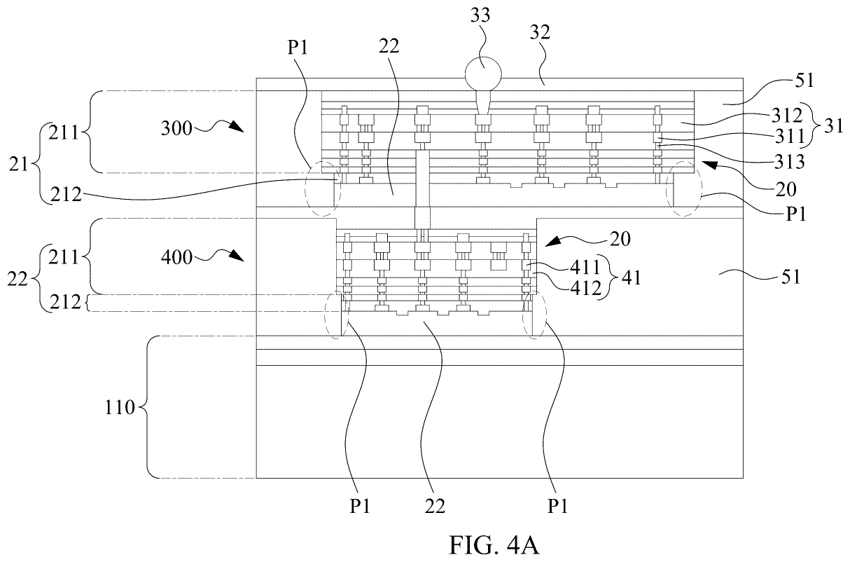

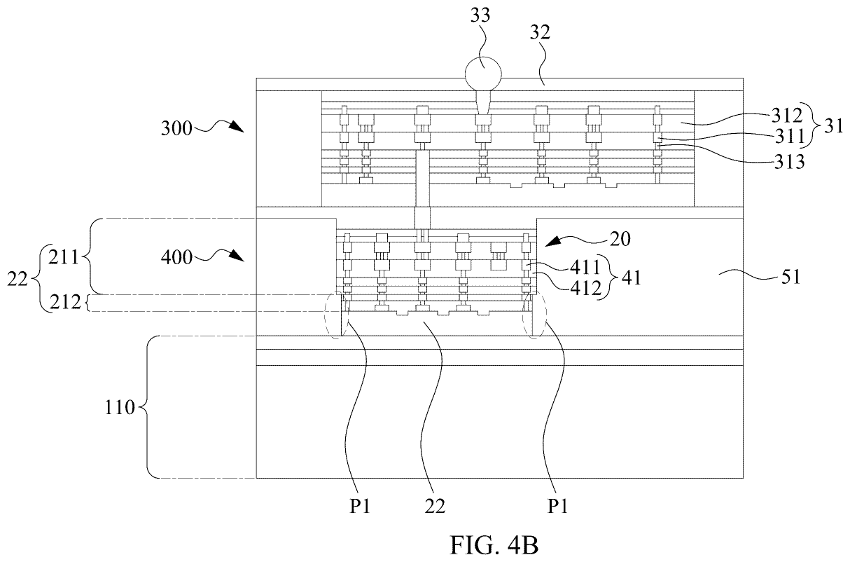

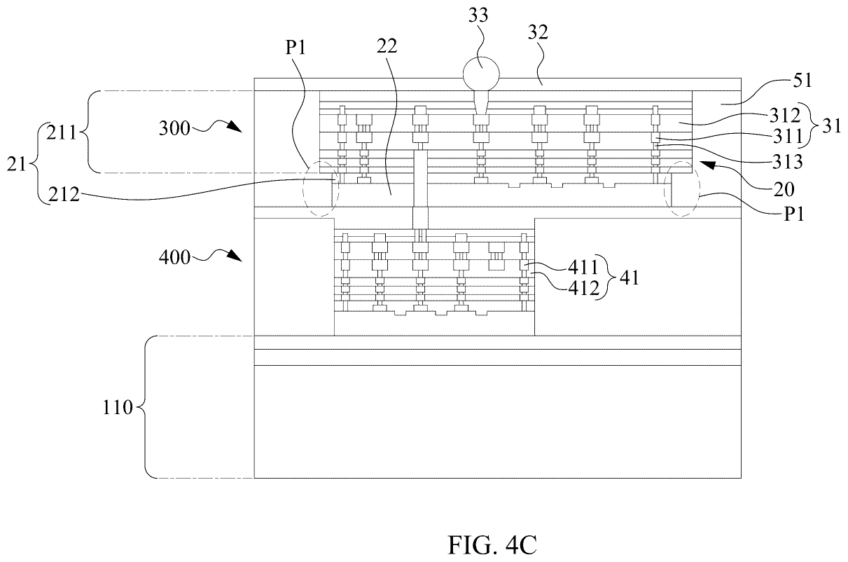

FIG. 4A illustrates a cross-sectional view of several three-dimensionally (3D) stacking dies 300 and 400 in accordance with some embodiments. An upper 3D stacking die 300 includes the bottom structure 21 and the top structure 22 of the present disclosure, which are encapsulated by first molding structures 51. The lower portion 211 of the bottom structure 21 may comprise a back-end structure including an interconnect structure 31 and a metal bump 33. The interconnect structure 31 is formed on the upper portion 212 of the bottom structure 21 located on the top structure 22 and is used to electrically connect to the integrated circuit devices. The interconnect structure 31 may include a plurality of stacked alternating metal lines 311 and dielectric layers 312, which may include interlayer dielectric (ILD) and inter-metal dielectric (IMDs). The metal lines 311 are formed in dielectric layers 312, wherein the metal lines 311 that are in a same dielectric layer 312 are in combination referred to as a metal layer. Vias 313 are formed between, and interconnecting, metal lines 311 in different metal layers. In an embodiment, dielectric layers 312 comprise at least one, and possibly a plurality of, low-k dielectric layer(s) having low k values. The k values of the low-k dielectric materials in dielectric layers 312 may be lower than about 3.0, or lower than about 2.5, for example. In an embodiment, passivation layer(s) 32 are formed over the dielectric layers 312. Additional layers such as polyimide layers (not shown), post-passivation interconnects (PPIs, not shown), may also be formed. Metal bump 33 can be formed at the surface of the upper 3D stacking die 300. In an embodiment, the metal bumps 33 can be a copper bump. In alternative embodiments, the metal bump 33 is a solder bump, or composite bump comprising copper post, nickel layer, solder cap, and/or the like. In some embodiments, the upper portion 212 of the bottom structure 21 can be a middle-end structure. The top structure 22 can be a front-end structure.

The lower 3D stacking die 400 includes the bottom structure 21 and the top structure 22 as described in the present disclosure encapsulated by first molding structures 51, which are bonded onto a first carrier 110. In this embodiment, the upper 3D stacking die 300 serves as the substrate 10 holding the lower 3D stacking die 400. The lower portion 211 of the bottom structure 21 may comprise a back-end structure including an interconnect structure 41. The interconnect structure 41 may include a plurality of stacked alternating metal lines 411 and dielectric layers 412, which may include interlayer dielectric (ILD) and inter-metal dielectric (IMDs) as described above. In some embodiments, the upper portion 212 of the bottom structure 21 can be a middle-end structure and a portion of the back-end structure. The top structure 22 can be a front-end structure.

In some embodiments as shown in FIG. 4A, each of the upper 3D stacking die 300 and the lower 3D stacking die 400 includes the profile (as circulated in circle P1) of the bottom structure 21 and the top structure 22 of the present disclosure. In some alternative embodiments as shown in FIG. 4B, the lower 3D stacking die 400 includes the profile P1 of the bottom structure 21 and the top structure 22 of the present disclosure. In some another embodiments as shown in FIG. 4C, the upper 3D stacking die 300 includes the profile P1 of the bottom structure 21 and the top structure 22 of the present disclosure.

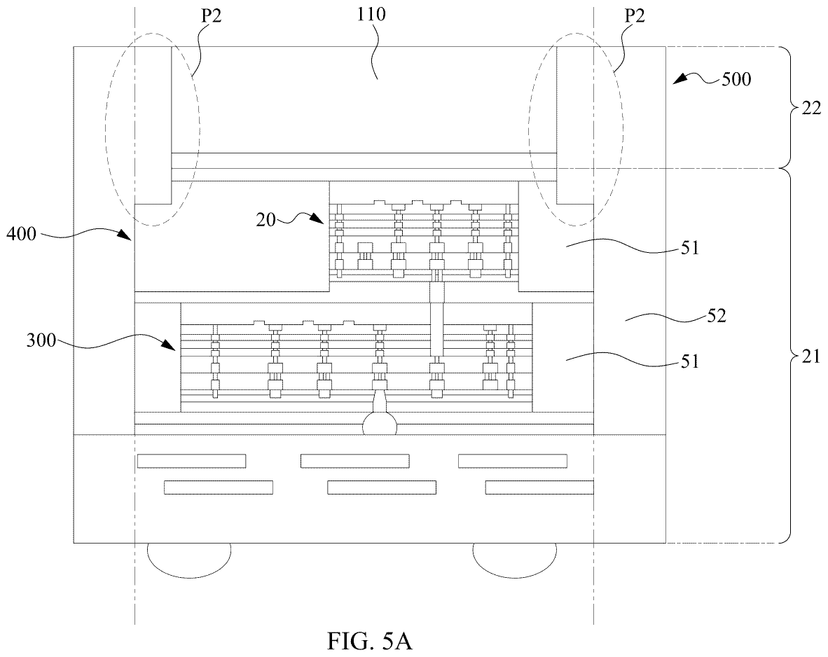

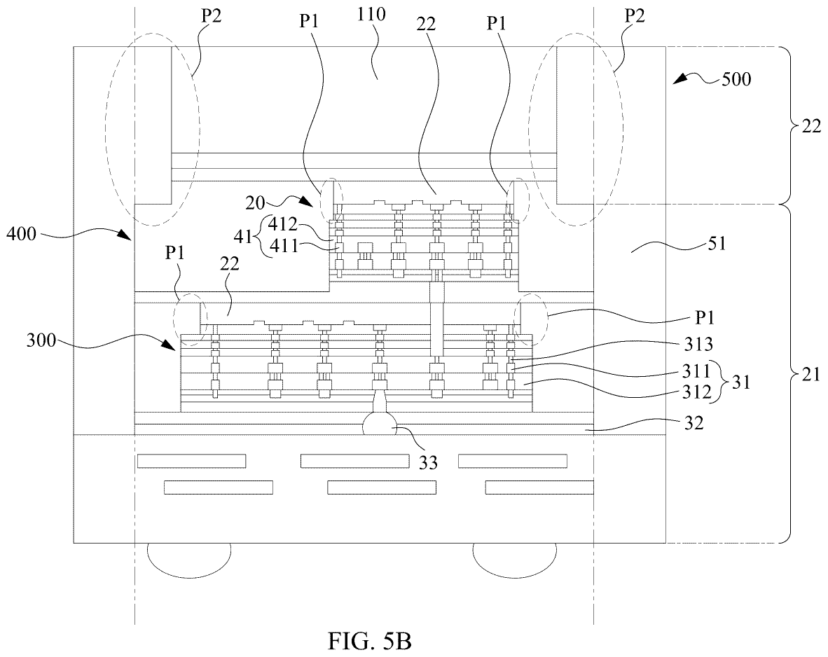

FIG. 5A shows a packaged semiconductor device 500 comprising a bottom structure 21, a top structure 22 and second molding structures 52 surrounding the bottom structure 21 and the top structure 22. The packaged semiconductor device 500 includes the profile (as circulated in circle P2) of the bottom structure 21 and the top structure 22 of the present disclosure. The packaged semiconductor device 500 can be referred to as a Package-on-Package (PoP) structure. In accordance with some embodiments of the present disclosure, the packaged semiconductor device 500 includes a plurality of device structure units 20, which may be memory dies such as Static Random Access Memory (SRAM) dies, Dynamic Random Access Memory (DRAM) dies, or the like. The molding structures 51 may include insulating materials, such as a polymer, a resin, an epoxy, or the like. For example, the molding structures 51 may be a carbon-based polymer.

As shown in FIG. 5B, the packaged semiconductor device 500 may comprise the several three-dimensionally (3D) stacking dies 300 and 400 illustrated in FIG. 4A, which are encapsulated by second molding structures 52. The packaged semiconductor device 500 includes the profiles P1 and P2 of the bottom structure 21 and the top structure 22 of the present disclosure. The semiconductor structures illustrated in FIGS. 4A, 4B, 4C, 5A and 5B are merely examples and are not intended to be limiting. Any semiconductor structures including the bottom structure 21 and the top structure 22 are within the scope of the present disclosure.

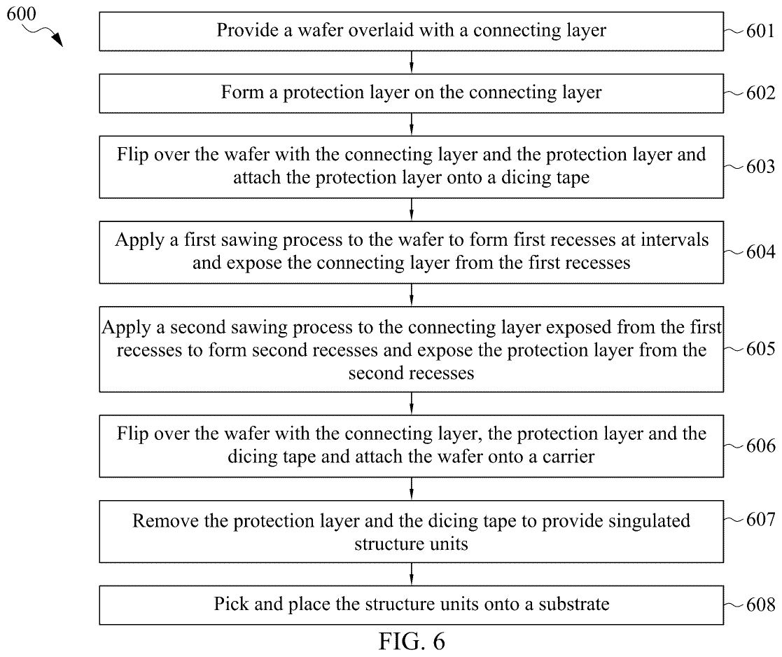

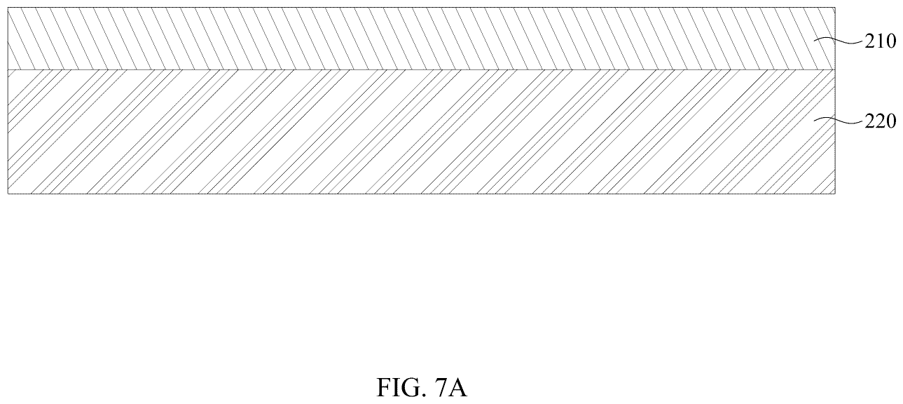

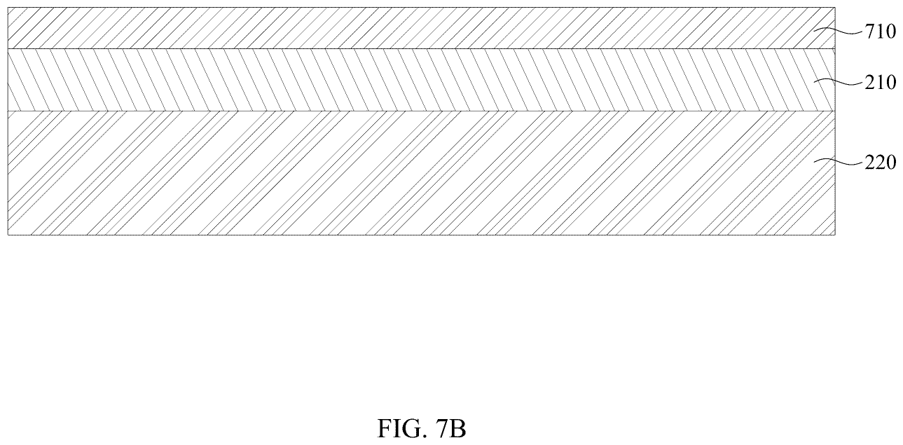

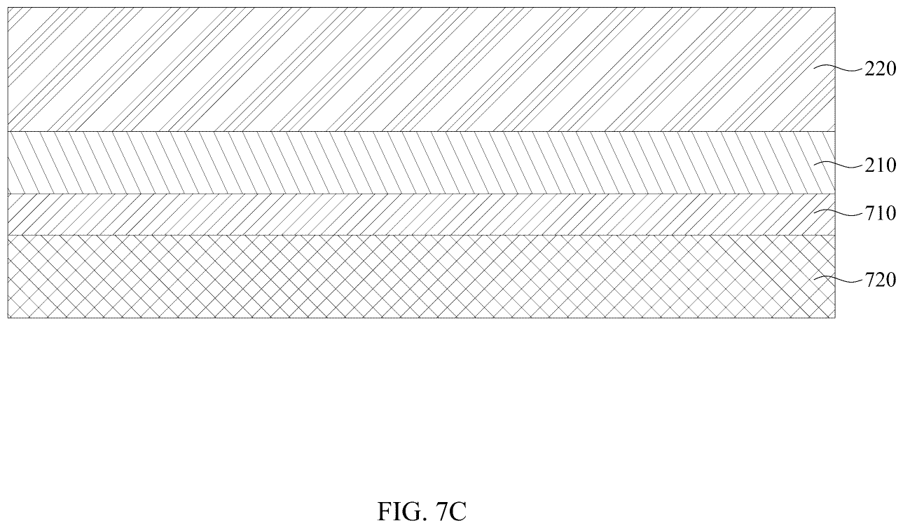

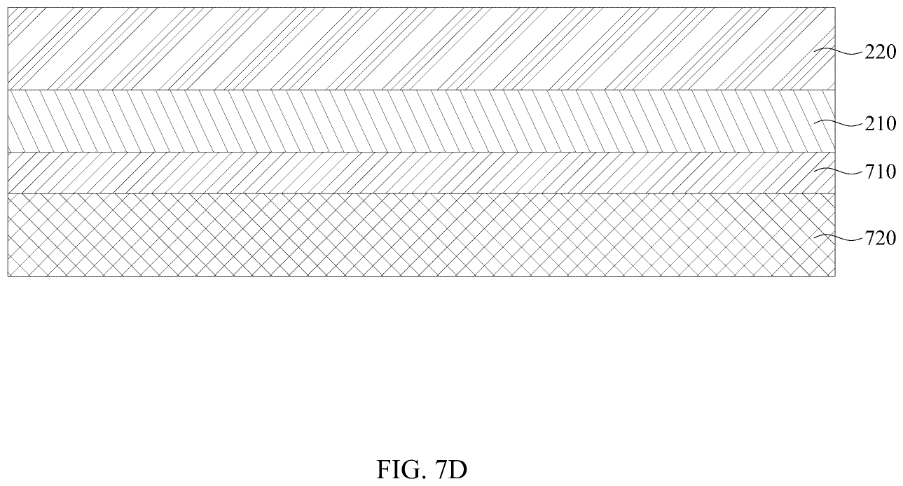

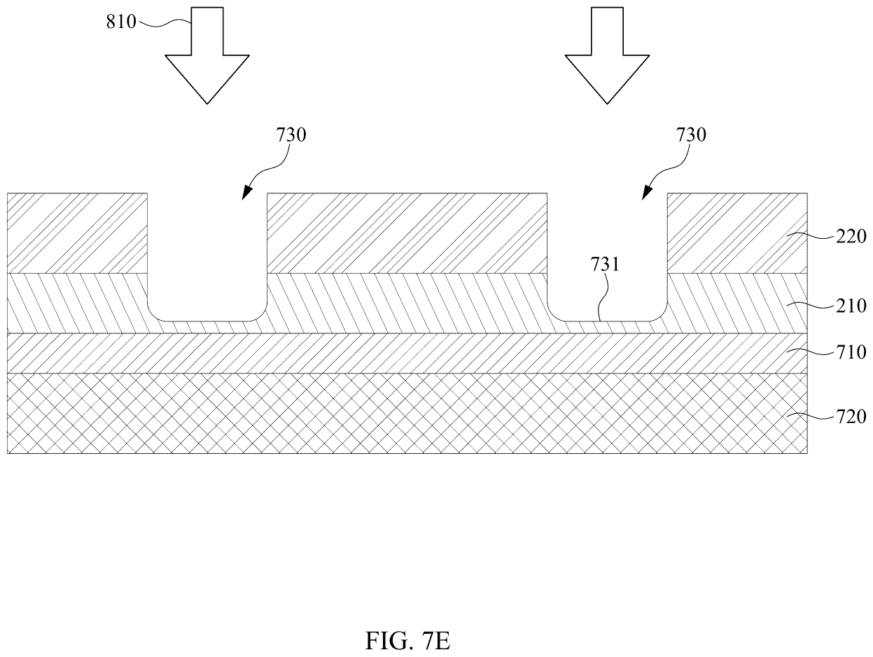

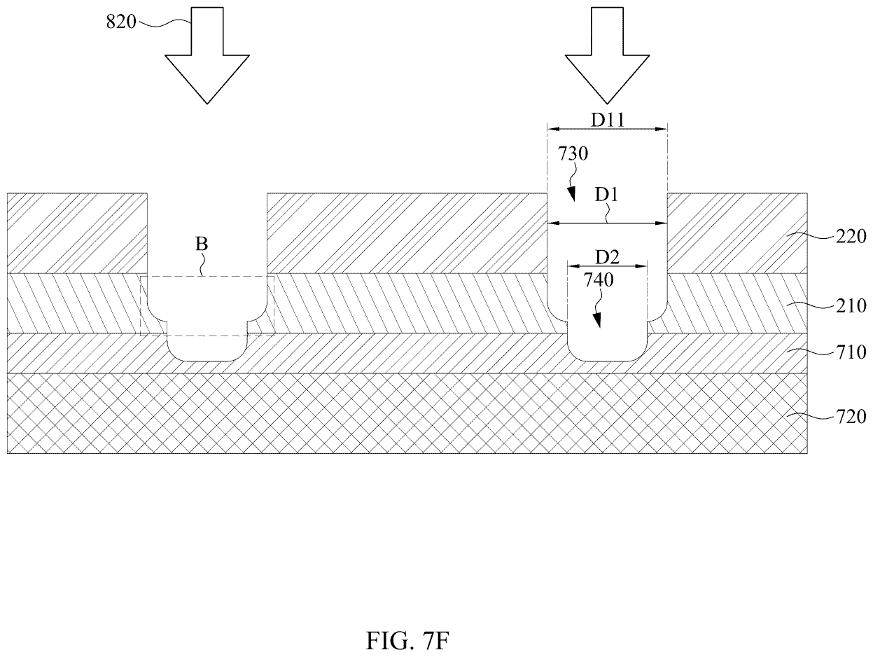

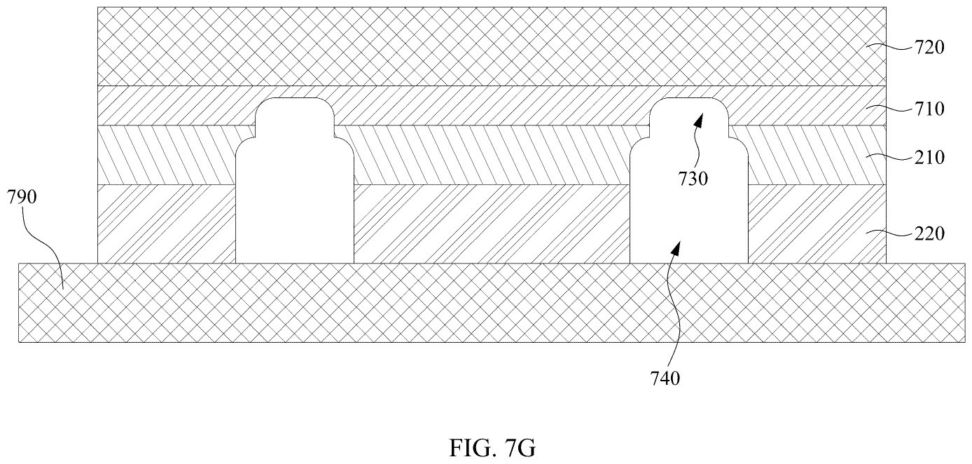

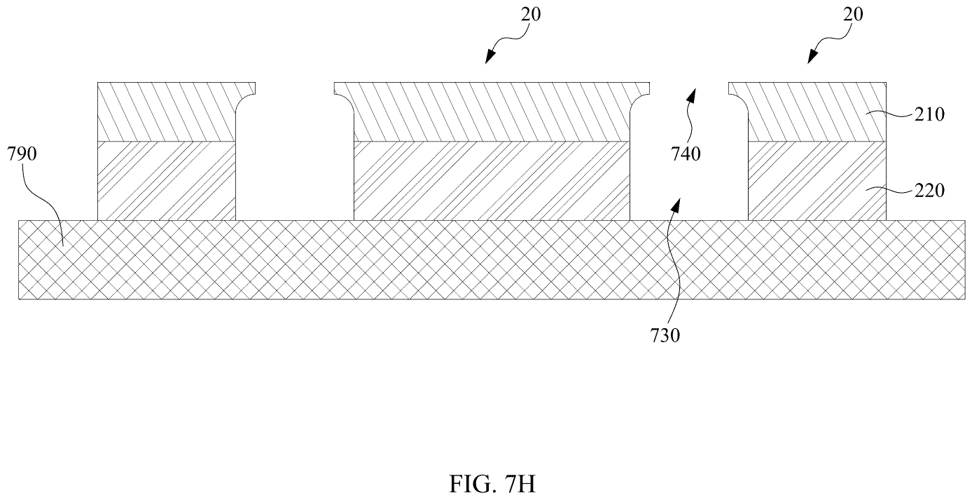

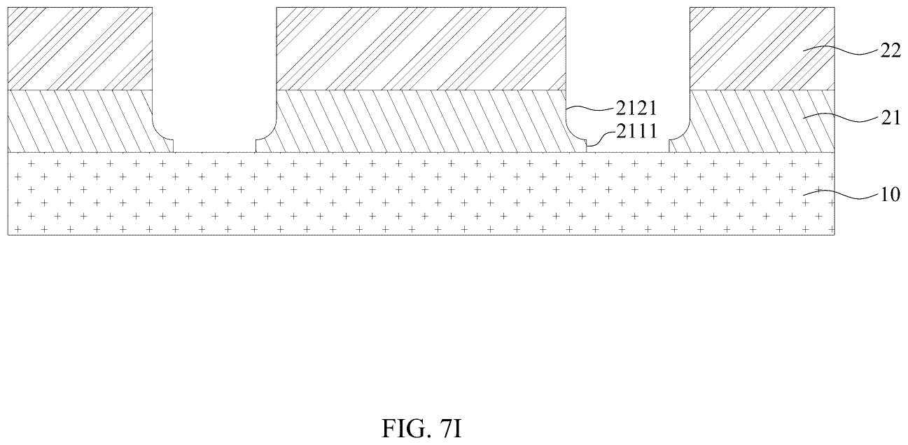

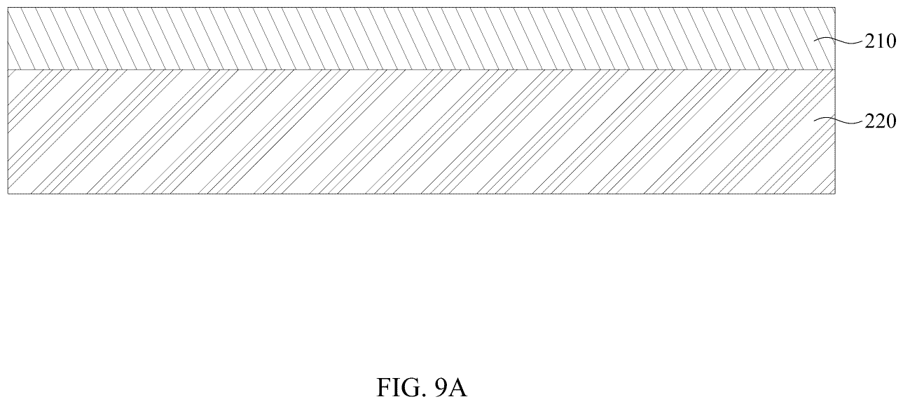

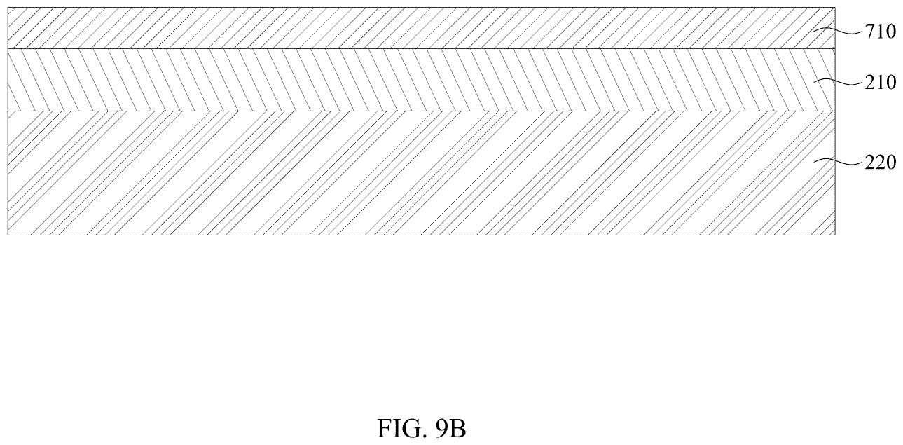

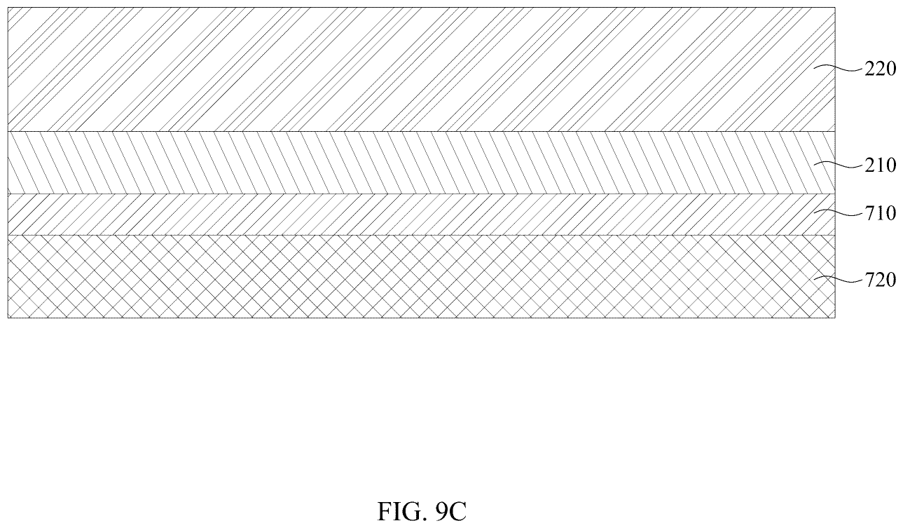

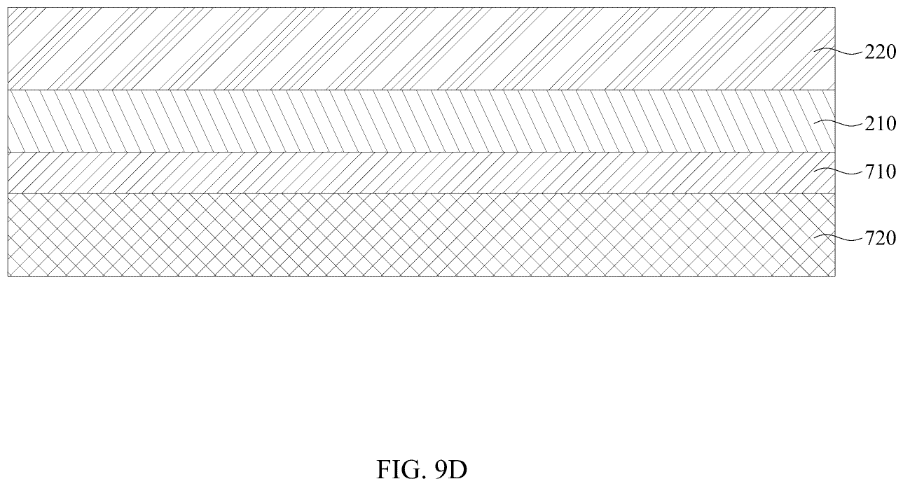

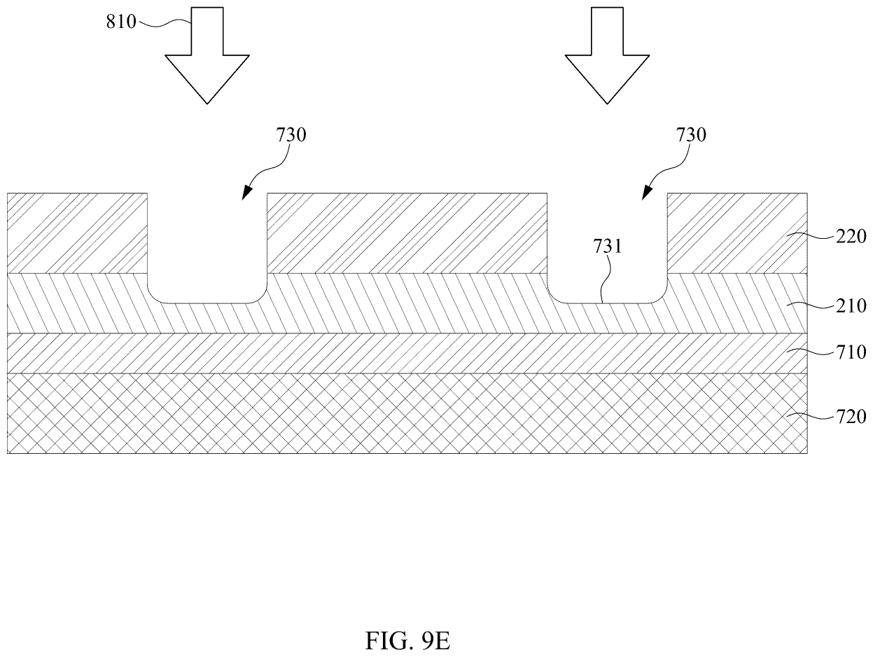

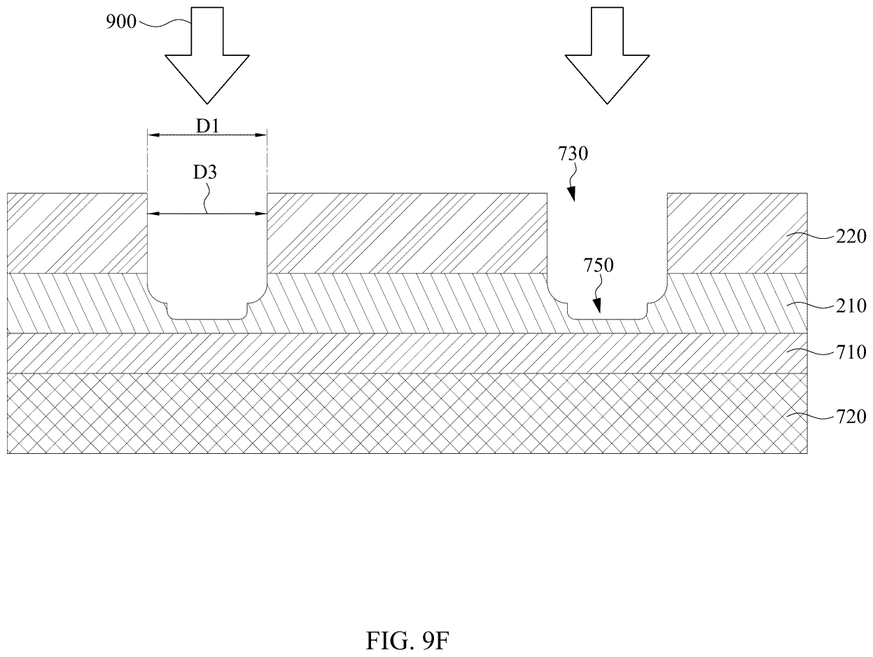

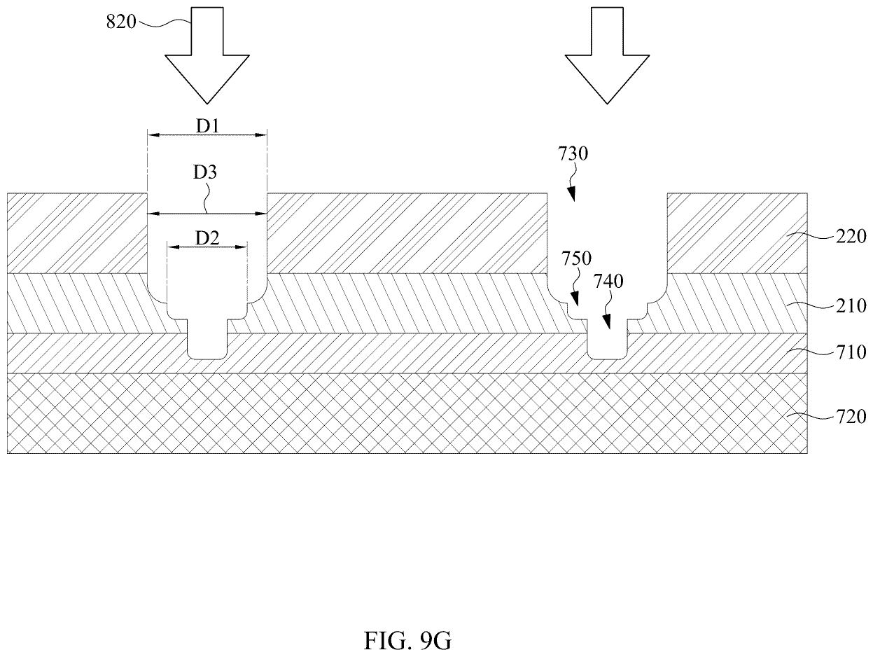

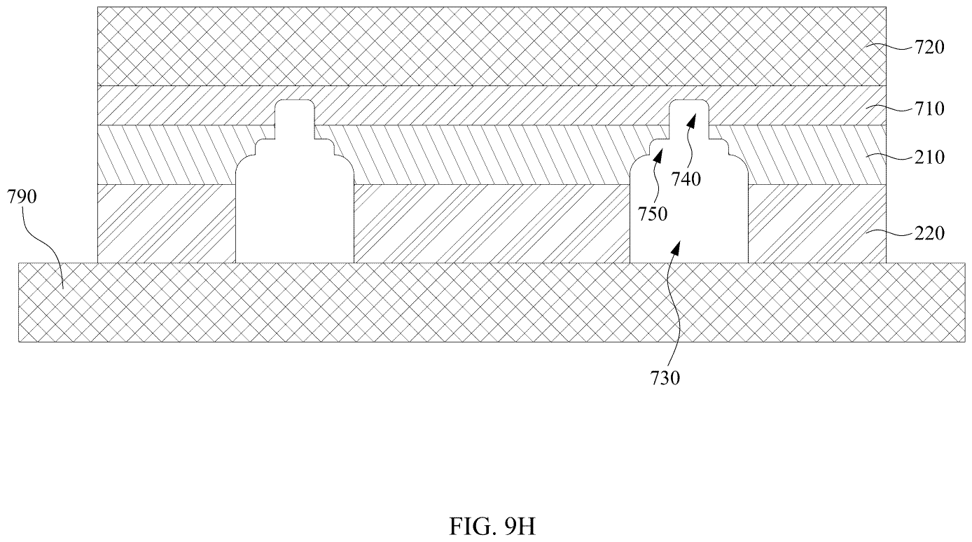

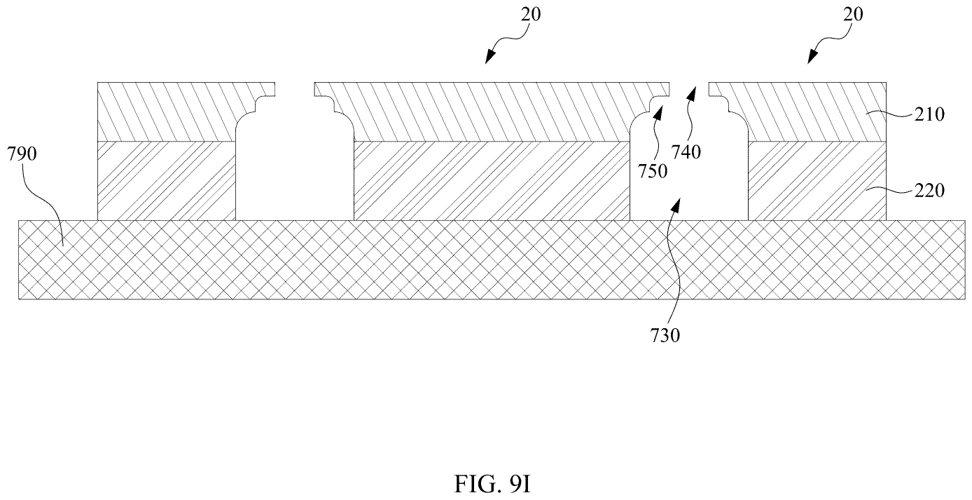

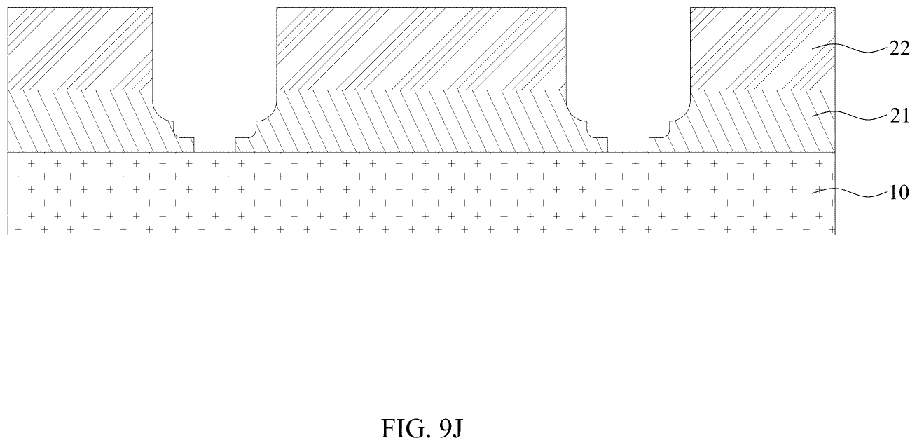

FIG. 6 is a flowchart representing a method 600 for forming a semiconductor structure according to various aspects of the present disclosure. In some embodiments, the method 600 for forming the semiconductor structure includes a number of operations (601, 602, 603, 604, 605, 606, 607 and 608). The method 600 for forming the semiconductor structure will be further described according to one or more embodiments. It should be noted that the operations of the method 600 may be rearranged or otherwise modified within the scope of the various aspects. It should further be noted that additional processes may be provided before, during, and after the method 600, and that some other processes may be only briefly described herein. FIGS. 7A to 7I and 9A to 9J are diagrammatic perspective views illustrating various stages in the method 600 for forming the semiconductor structure according to aspects of one or more embodiments of the present disclosure.

With reference to FIG. 7A, the method 600 begins at operation 601 where a wafer 220 is overlaid with a connecting layer 210. The connecting layer 210 may include, but not limited to, at least a portion of a front-end structure, at least a portion of a middle-end structure, at least a portion of a back-end structure, both of the front-end structure and the middle-end structure, both of the back-end structure and the middle-end structure, three-dimensionally (3D) stacking dies and so on. In some embodiments, the connecting layer 210 may comprise various device structures, including but not limited to one or more high power transistors (e.g., vertical double diffused metal oxide semiconductor (VDMOS) devices, double diffused drain metal oxide semiconductor (DDDMOS) devices, lateral diffused metal oxide semiconductor (LDMOS) devices; drain extended metal oxide semiconductor (DEMOS) devices; and insulated-gate bipolar transistor (IGBT), high power field-effect transistors (HPFET) devices, etc.). In some embodiments, the connecting layer 210 includes one or more epitaxially disposed layers for the purpose of strained channel formation, retrograde doping, heterostructure band formation, carrier mobility improvement, breakdown voltage improvement, and the like.

Then, at operation 602 as shown in FIG. 7B, a protection layer 710 is formed on the connecting layer 210. The protection layer 710 can be any materials, which can avoid direct attachment of the connecting layer 210 onto a dicing tape 720 to be used in the next operation and avoid damage to the connecting layer 210. In some embodiments, the protection layer 710 may be a photoresist material, an organic material, a polymer material, other materials that solidify after curing, and/or combinations thereof, in some embodiments, for example. In some embodiments, the protection layer 710 comprises polybenzoxazole (PBO), as an example. The protection layer 710 is formed in some embodiments using a spin-on method, chemical vapor deposition (CVD), a spin coating process, a printing process, or other coating methods, as examples. Alternatively, the protection layer 710 may comprise other materials, dimensions, and formation methods.

As shown in FIG. 7C, the method 600 continues with operation 603 where the wafer 220 with the connecting layer 210 and the protection layer 710 is flipped over and attached onto a dicing tape 720, so that the protection layer 710 is bonded onto the dicing tape 720. In some embodiments, the dicing tape 720 has an adhesive surface that is used to attach to the protection layer 710. In some embodiments, the dicing tape 720 may be formed of an adhesive. In some alternative embodiments, the dicing tape 720 may be UV erasable. In other words, the dicing tape 720 may lose strength on exposure to UV.

As shown in FIG. 7D, a thinning process may be applied to the wafer 220 in accordance with various embodiments of the present disclosure. The thinning process can employ a mechanical grinding process, a chemical polishing process, an etching process and/or the like. By employing the thinning process, one side of the wafer 220 opposite to the connecting layer 210 can be ground so that a thickness of the wafer 220 can be reduced. In some alternative embodiments, the wafer 220 may not thinned.

At operation 604 as shown in FIG. 7E, a first sawing process 810 is applied to the wafer 220 to form a plurality of first recesses 730 at intervals (i.e., scribe lines) so as to expose the connecting layer 210 from a bottom 731 of the first recesses 730. Each of the first recesses 730 has a first diameter D1. The first sawing process 810 includes, but not limited to a blade sawing, a laser grooving, a plasma dicing, a solid-impact surface treatment (such as sandblasting), a non-solid-impact surface treatment (such as water gun) or the like, or a combination thereof. The method for performing the first sawing process 810 can be chosen according to materials of the connecting layer 210 and/or the wafer 220, dimension of the first recesses 730 to be formed and so on. In some embodiments, the first sawing process 810 may be a blade sawing.

At operation 605 as shown in FIG. 7F, a second sawing process 820 is applied to the connecting layer 210 exposed from the bottom 731 of the first recesses 730 to form second recesses 740 so as to expose the protection layer 710 from the second recesses 740. Each of the second recesses 740 has a second diameter D2, which can be less than the first diameter D1 of the first recess 730. The second sawing process 820 includes, but not limited to a blade sawing, a laser grooving, a plasma dicing, a solid-impact surface treatment (such as sandblasting), a non-solid-impact surface treatment (such as water gun) or the like, or a combination thereof. The method for performing the second sawing process 820 can be chosen according to materials of the connecting layer 210 and/or the protection layer 710, dimension of the second recesses 740 to be formed and so on. In some embodiments, the second sawing process 820 may be a laser grooving.

Each of the second recesses 740 has a second diameter D2, which can be less than the first diameter D1 of the first recess 730, so that the connecting layer 210 has gradually increased width from a top contacting the wafer 220 to a bottom contacting the protection layer 710 and thus has a curved sidewall.

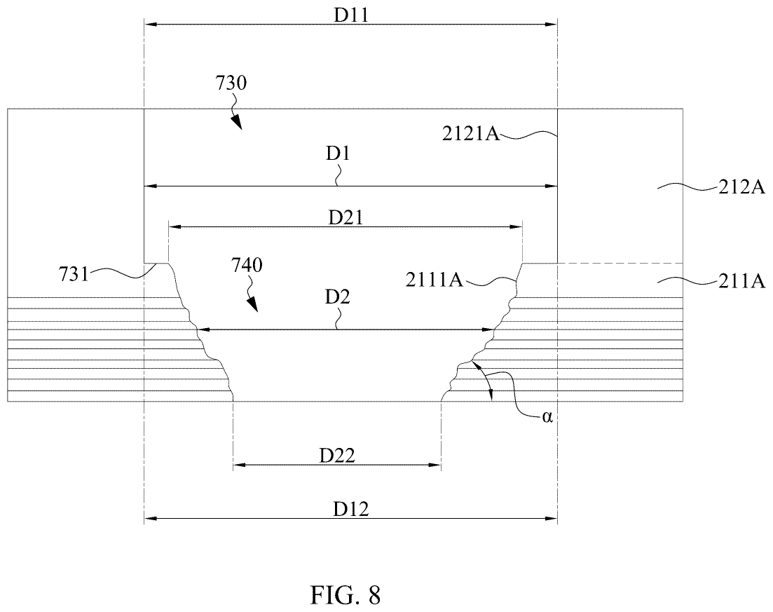

As shown in FIG. 8, the first recess 730 may have a top with a top diameter D11 and a bottom with a bottom diameter D12. The top diameter D11 of the first recess 730 may be substantially identical to or different from the bottom diameter D12 of the first recess 730. The first diameter D1 of the first recess 730 can be an average of the top diameter D11 and the bottom diameter D12. In some embodiments, the top diameter D11 of the first recess 730 may be substantially identical to the bottom diameter D12 of the first recess 730 so that the first recess 730 has a rectangular cross section. The second recess 740 may have a top with a top diameter D21 and a bottom with a bottom diameter D22. The top diameter D21 of the second recess 740 may be substantially identical to or different from the bottom diameter D22 of the second recess 740. The second diameter D2 of the second recess 740 can be an average of the top diameter D21 and the bottom diameter D22. In some embodiments, the bottom diameter D22 of the second recess 740 can be less than the top diameter D21 of the second recess 740 so the second recesses 740 has a substantial reversed-trapezoid cross-section. In some embodiments, the bottom diameter D12 of the first recess 730 may be substantially identical to the top diameter D21 of the second recess 740 so that sidewall of the second recesses 740 continuously extends from sidewall of the first recesses 730. In some another embodiments as shown in FIG. 8, the top diameter D21 of the second recess 740 is less than the bottom diameter D12 of the first recess 730 so that the sidewall of the second recesses 740 discontinuously extends from sidewall of the first recesses 730. As shown in FIG. 8, edge portions of the bottom 731 of the first recesses 730 may be retained after the second sawing process 820. The sidewall of the first recesses 730 may be smooth or rugged. The sidewall of the second recesses 740 may be smooth or rugged. In some embodiments as illustrated in FIG. 8, the sidewall of the first recesses 730 is substantially smooth and the sidewall of the second recesses 740 is rugged.

The method 600 then proceeds to operation 606, in which the wafer 220 with the connecting layer 210, the protection layer 710 and the dicing tape 720 are flipped over and is attached onto a carrier 790 as shown in FIG. 7G.

As shown in FIG. 7H, at operation 607, the protection layer 710 and the dicing tape 720 are removed so as to expose the carrier 790 from the first recesses 730 and the second recesses 740 and thus provide singulated structure units 20 separated by the first recesses 730 and second recesses 740. Then, at operation 608, the structure units 20 can be picked and placed onto a substrate 10 as shown in FIG. 7I by a pick-and-place device. The structure unit 20 comprises a bottom structure 21 and a top structure 22 as shown in FIGS. 1A and 3A; therefore, the details of the bottom structure 21 and the top structure 22 are omitted in the interest of Brevity.

FIGS. 9A to 9J illustrate various stages in the method 600 for forming the semiconductor structure in accordance with some another embodiments of the present disclosure. Operations 601 to 604 and 606 to 608 shown in FIGS. 9A to 9E and 9H to 9J are substantially identical to those illustrated in FIGS. 7A to 7E and 7G to 7I; therefore, the descriptions of operations 601 to 604 and 606 to 608 are omitted in the interest of brevity.

After performing operation 604, at least one further sawing process 900 can be performed to the connecting layer 210 to form further recesses 750 as shown in FIG. 9F, so the connecting layer 210 can be exposed from a bottom 751 of the further recesses 750. Each of the further recesses 750 has a third diameter D3, which can be less than the first diameter D1 of the first recess 730. The further sawing process 900 includes, but not limited to a blade sawing, a laser grooving, a plasma dicing, a solid-impact surface treatment (such as sandblasting), a non-solid-impact surface treatment (such as water gun) or the like, or a combination thereof. The method for performing the first sawing process 810 can be chosen according to materials of the connecting layer 210, dimension of the further recesses 750 to be formed and so on. In some embodiments, the further sawing process 900 may be a laser grooving.

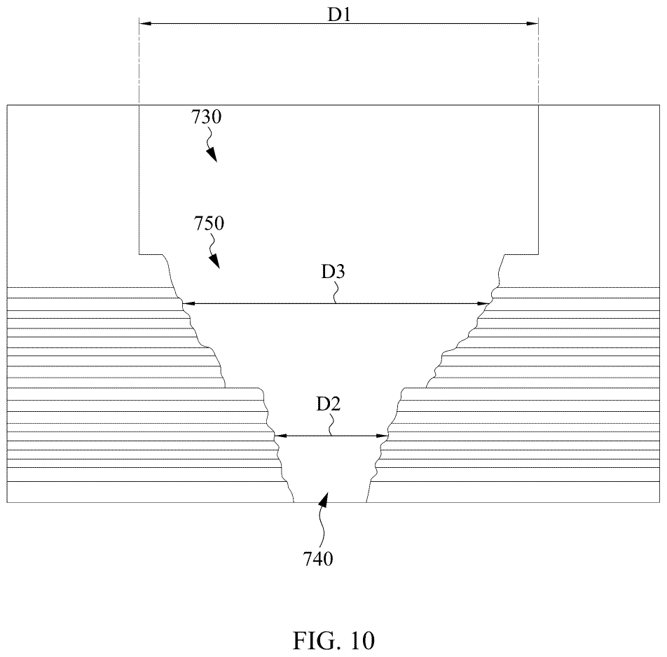

After forming the further recesses 750, operation 605 is performed as shown in FIG. 9G, a second sawing process 820 is applied to the connecting layer 210 exposed from the bottom 751 of the further recesses 750 to form second recesses 740 so as to expose the protection layer 710 from the second recesses 740. Each of the second recesses 740 has a second diameter D2, which can be less than the first diameter D1 of the first recess 730 and also less than the third diameter D3 of the further recess 750 as shown in FIG. 10. As shown in FIG. 10, sidewall of the first recesses 730 may be smooth or rugged; sidewall of the further recess 750 may be smooth or rugged; and sidewall of the second recesses 740 may be smooth or rugged. The second sawing process 820 includes, but not limited to a blade sawing, a laser grooving, plasma dicing, a solid-impact surface treatment (such as sandblasting), a non-solid-impact surface treatment (such as water gun) or the like, or a combination thereof. The method for performing the second sawing process 820 can be chosen according to materials of the connecting layer 210 and/or the protection layer 710, dimension of the second recesses 740 to be formed and so on. In some embodiments, the second sawing process 820 may be a laser grooving. After the operation 605, operation 606 can be followed.

Blade sawing can fast remove unwanted materials and is suitable for large process window while a laser grooving can avoid the thermal and mechanical stress created by the blade saw but takes longer than a blade sawing and thus is suitable for small process window. By using a blade sawing to form first recesses 730 and extending the first recesses 730 through the connecting layer 210 with the laser grooving, the dimension of the second recesses 740 can be finely controlled, and thus provides the connecting layer 210 with a gradually increased width so as to avoid voids formed beside the connecting layer 210. Therefore, the performance of the semiconductor structure can be improved.

In some embodiments, a method for forming a semiconductor structure, comprises providing a wafer overlaid with a connecting layer; forming a protection layer on the connecting layer; flipping over the wafer with the connecting layer and the protection layer and attaching the protection layer onto a dicing tape; applying a first sawing process to the wafer to form first recesses at intervals and expose the connecting layer from the first recesses; applying a second sawing process to the connecting layer exposed from the first recesses to form second recesses and expose the protection layer from the second recesses; flipping over the wafer with the connecting layer, the protection layer and the dicing tape and attaching the wafer onto a carrier; and removing the protection layer and the dicing tape to provide singulated structure units, wherein a width of each of the first recesses is greater than a width of a corresponding one of the second recesses communicating with the each of the first recesses.

In some embodiments, a method for forming a semiconductor structure, comprises providing a wafer overlaid with a connecting layer and a protection layer; attaching the protection layer onto a dicing tape; applying two or more sawing processes to the wafer to form recesses in the wafer and the connecting layer to expose the protection layer from the recesses; flipping over the wafer with the connecting layer, the protection layer and the dicing tape; and removing the protection layer and the dicing tape to provide singulated structure units.

In some embodiments, a semiconductor structure, comprises a substrate; and a plurality of structure units bonded onto the substrate and each of the plurality of structure units comprising: a bottom structure bonded onto the substrate and having a width gradually increased from a top to a bottom; and a top structure formed on the bottom structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for manufacturing a semiconductor structure, comprising:
providing a wafer overlaid with a connecting layer;
forming a protection layer on the connecting layer;
flipping over the wafer with the connecting layer and the protection layer and attaching the protection layer onto a dicing tape;
applying a first sawing process to the wafer to form first recesses at intervals and expose the connecting layer from the first recesses;
applying a second sawing process to the connecting layer exposed from the first recesses to form second recesses and expose the protection layer from the second recesses;
flipping over the wafer with the connecting layer, the protection layer and the dicing tape and attaching the wafer onto a carrier; and
removing the protection layer and the dicing tape to provide singulated structure units,
wherein a width of each of the first recesses is greater than a width of a corresponding one of the second recesses communicating with the each of the first recesses.

2. The method of claim 1, wherein the each of the first recesses has a top with a top diameter and a bottom with a bottom diameter, and the top diameter of the first recess is substantially identical to or different from the bottom diameter of the first recess; and wherein the corresponding one of the second recesses has a top with a top diameter and a bottom with a bottom diameter, and the top diameter of the second recess is substantially identical to or different from the bottom diameter of the second recess.

3. The method of claim 2, wherein the top diameter of the second recess is greater than the bottom diameter of the second recesses, so that the second recess has a substantial reversed-trapezoid cross-section.

4. The method of claim 2, wherein the bottom diameter of the first recess is greater than the t op diameter of the second recess.

5. The method of claim 1, wherein a sidewall of the first recess is smooth or rugged; and a sidewall of the second recess is smooth or rugged.

6. The method of claim 1, wherein the first sawing process is a blade sawing and the second sawing process is a laser grooving.

7. The method of claim 1, further comprising a thinning process applied to the wafer after attaching the protection layer onto the dicing tape and before applying the first sawing process.

8. The method of claim 1, further comprising applying at least one further sawing process to the connecting layer to form further recesses to expose the device layer from a bottom of the further recesses after applying the first sawing process and before applying the second sawing process.

9. A method for manufacturing a semiconductor structure, comprising:
providing a wafer overlaid with a connecting layer and a protection layer;
attaching the protection layer onto a dicing tape;
applying two or more sawing processes to the wafer to form recesses in the wafer and the connecting layer to expose the protection layer from the recesses;
flipping over the wafer with the connecting layer, the protection layer and the dicing tape; and
removing the protection layer and the dicing tape to provide singulated structure units.

10. The method of claim 9, wherein the recesses at a deeper depth has a diameter less than a diameter of the recesses at a shallower depth.

11. The method of claim 9, wherein the recesses at a shallower depth are formed before a formation of the recesses at a deeper depth.

12. The method of claim 9, wherein the two or more sawing processes are selected from a blade sawing, a laser grooving, a plasma dicing, a solid-impact surface treatment, a non-solid-impact surface treatment or a combination thereof.

13. The method of claim 9, wherein the recesses at a shallower depth are formed by a blade sawing and the recesses at a deeper depth are formed by a laser grooving.

14. The method of claim 9, further comprising a thinning process applied to the wafer after attaching the protection layer onto the dicing tape and before applying the two or more sawing processes.

15. A semiconductor structure, comprising:
a substrate; and
a plurality of structure units bonded onto the substrate and each of the plurality of structure units comprising:
a bottom structure bonded onto the substrate and having a width gradually increased from a top to a bottom; and
a top structure formed on the bottom structure.

16. The semiconductor structure of claim 15, wherein the bottom structure comprises:
a lower portion comprising:
a bottom having a first width; and
a top having a second width,
wherein a ratio of the first width to the second width ranges from about 1:1 to about 10:1.

17. The semiconductor structure of claim 16, wherein the bottom structure further comprises an upper portion over the lower portion, and the upper portion has a third width and a ratio of the first width to the third width ranges from about 1:1 to about 15:1, and a ratio of the third width to the second width ranges from about 100:99 to about 2:1.

18. The semiconductor structure of claim 16, wherein the lower portion has a lower sidewall and an angle between the bottom of the lower portion and the lower sidewall is less than about 90 degrees and greater than 0 degrees.

19. The semiconductor structure of claim 16, wherein the lower portion has a lower sidewall, which is smooth or rugged.

20. The semiconductor structure of claim 17, wherein
the lower portion has a lower sidewall, which is formed after being treated with a blade sawing; and
the upper portion has an upper sidewall, which is formed after being treated with a laser grooving.
